(19) United States
(12) Patent Application Publication
(10) Pub. No.: US 2010/0124724 A1
(43) Pub. Date: May 20, 2010

(54) PROJECTION EXPOSURE APPARATUS, METHOD FOR CALIBRATING MEASUREMENT CRITERION OF DISPLACEMENT MEASUREMENT UNIT, AND METHOD FOR MANUFACTURING DEVICE

(75) Inventors: Tomohiro Hoshino, Utsunomiya-shi (JP); Toshiyuki Yoshihara, Utsunomiya-shi (JP)

Correspondence Address: CANON U.S.A. INC. INTELLECTUAL PROPERTY DIVISION, 15975 ALTON PARKWAY, IRVINE, CA, 92618-3731, US

(73) Assignee: CANON KABUSHIKI KAISHA, Tokyo (JP)

(21) Appl. No.: 12/621,371

(22) Filed: Nov. 18, 2009

(30) Foreign Application Priority Data
Nov. 20, 2008 (JP) 2008-296692

(51) Int. Cl. G03F 7/20; G03B 27/54; G01B 11/14; G03B 27/52; G03B 27/68

(52) U.S. Cl. 430/325; 355/67; 356/614; 355/55; 355/52

(57) ABSTRACT

A projection exposure apparatus includes an optical element, and projects a pattern formed on a first object onto a second object to be exposed through a projection optical system for correcting imaging characteristics by controlling the optical element. The projection exposure apparatus includes: a displacement measurement unit configured to measure a displacement of the optical element; a storage unit configured to store a measurement criterion of the displacement measurement unit; an imaging characteristics measurement unit configured to measure imaging characteristics of the projection optical system; and a calibration unit configured to calibrate the measurement criterion based on a result of measurement by the imaging characteristics measurement unit.

### BACKGROUND OF THE INVENTION

1. Field of the Invention

The present invention relates to a projection exposure apparatus and a method for manufacturing a device, and is preferably used for a lithography process in manufacturing processes of semiconductor devices such as ICs and LSIs, imaging devices such as CCDs, display devices such as liquid crystal display (LCD) panels, and other devices such as magnetic heads.

2. Description of the Related Art

In recent years, with the increase in the integration of semiconductor devices, demands for high-precision microscopic circuit pattern processing technologies has been becoming more and more stringent. Accordingly, an excellent imaging performance is required for a projection optical system of a projection exposure apparatus used for the above-mentioned device manufacture. To meet such demands, various correction methods have been proposed, for example, a method for correcting the drive of a lens, a mirror, and other optical elements by using a mechanism for controlling the volume or pressure of a fluid, and a method for controlling the position and posture of a lens by applying a force to an elastic member via which lens-retaining members are connected to each other.

A method for correcting imaging characteristics by changing the position and posture of an optical element in this way controls the optical element based on measurement values of a displacement sensor for measuring the position, posture and distortion of the optical element.

However, if an output value of the displacement sensor changes by aging regardless of variation of the optical element and therefore an origin position (reference position) for displacement measurement deviates (hereinafter referred to as origin shift), the optical element cannot be retained and controlled at an optimal position. As a result, favorable exposure performance may not be obtained.

Japanese Patent Application Laid-Open No. 9-106944 discusses a method for retaining and controlling an optical element at an optimal position. With this method, a mechanical stop position is provided as a temporary origin position, a variation of an origin of a correction unit is calculated from changes in imaging characteristics through exposure operation, and the origin is calibrated based on the calculated variation.

Japanese Patent Application Laid-Open No. 2000-277412 discusses an exposure apparatus including a wave front measurement device employing the interference measurement method as a method for measuring imaging characteristics without actual exposure. Japanese Patent Application Laid-Open No. 5-41344 discusses a method for detecting an image plane state by receiving a reticle image with a photoelectric detector through a projection lens.

The method discussed in Japanese Patent Application Laid-Open No. 9-106944 cannot calibrate the origin of the displacement sensor if exposure conditions of a substrate are not observed after completing exposure of the substrate. Therefore, this method takes a lot of time and effort which may possibly affect the throughput.

The methods discussed in Japanese Patent Application Laid-Open No. 2000-277412 and Japanese Patent Application Laid-Open No. 5-41344 enable obtaining of an optimal position of an optical element by measuring imaging characteristics without observing a substrate that completed exposure processing. Therefore, it seems that these methods do not need to calibrate the origin of the displacement sensor and that an origin shift does not affect the exposure performance. However, the projection exposure apparatus utilizes a method for controlling the optical element based on a table prepared to correct changes in imaging characteristics due to environmental variation such as ambient temperature and atmospheric pressure changes. In this case, if an origin shift of the displacement sensor occurs, the position of the optical element corresponding to the output from the displacement sensor does not agree with the actual position of the optical element, making it difficult to obtain favorable exposure performance by using this method. If this method is not used, however, it becomes necessary to measure imaging characteristics each time environmental variation occurs, which may possibly affect the throughput.

### SUMMARY OF THE INVENTION

The present invention is directed to providing a projection exposure apparatus capable of calibrating an origin shift of a displacement measurement unit (displacement sensor) without observing a substrate after exposure.

A first aspect of the present invention is a projection exposure apparatus which includes an optical element, and projects a pattern formed on a first object onto a second object to be exposed through a projection optical system which corrects imaging characteristics by controlling the optical element. The projection exposure apparatus includes: a displacement measurement unit configured to measure a displacement of the optical element; a storage unit configured to store a measurement criterion of the displacement measurement unit; an imaging characteristics measurement unit configured to measure imaging characteristics of the projection optical system; and a calibration unit configured to calibrate the measurement criterion based on a result of measurement by the imaging characteristics measurement unit.

A second aspect of the present invention is a method for calibrating a measurement criterion of the displacement measurement unit used to measure a displacement of the optical element included in the projection optical system. The method includes measuring imaging characteristics of the projection optical system and calibrating the measurement criterion based on a result of the imaging characteristics measurement.

Further features and aspects of the present invention will become apparent from the following detailed description of exemplary embodiments with reference to the attached drawings.

### BRIEF DESCRIPTION OF THE DRAWINGS

The accompanying drawings, which are incorporated in and constitute a part of the specification, illustrate exemplary embodiments, features, and aspects of the invention and, together with the description, serve to explain the principles of the invention.

FIG. 1 schematically illustrates an essential part of the present invention.

FIG. 2 is a flow chart illustrating a first exemplary embodiment.

FIG. 3 is a graph illustrating a method for calibrating an origin.

FIG. 4 is a graph illustrating a change in imaging characteristics to describe a second exemplary embodiment.

FIG. 5 is a diagram illustrating the entire exposure apparatus.

### DESCRIPTION OF THE EMBODIMENTS

Various exemplary embodiments, features, and aspects of the invention will be described in detail below with reference to the drawings.

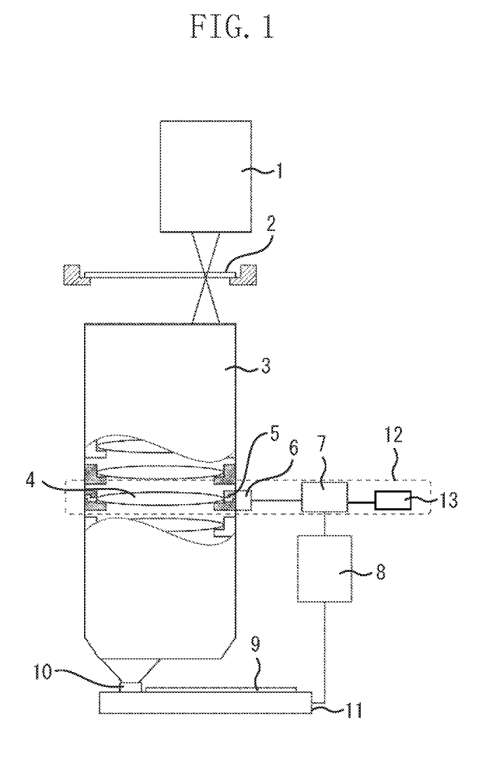

FIG. 1 schematically illustrates an essential part of an exemplary embodiment in which the present invention is applied to a projection exposure apparatus employing the step and scan method.

An illumination light formed by an illumination optical system 1 illuminates a reticle 2 (first object) with a circuit pattern, passes through a projection optical system 3, and projects an image of the circuit pattern onto a wafer 9 (second object) to be exposed. In the present exemplary embodiment, the projection optical system 3 includes an optical element 4, such as a lens or a mirror, and a drive actuator 5 for driving the optical element 4. The projection optical system 3 also includes a displacement sensor 6 (displacement measurement unit) for measuring a displacement of the optical element and a control unit 7 for controlling the drive actuator 5. A wafer stage 11 is provided with an imaging characteristics measurement unit 10 thereon for measuring imaging characteristics of the projection optical system 3. A correction unit 12 includes the optical element 4, the drive actuator 5, the displacement sensor 6, and a storage unit 13 such as memory for storing an origin position which is a measurement criterion. The correction unit 12 controls imaging characteristics of the projection optical system 3 based on a result of measurement by the imaging characteristics measurement unit 10 so as to appropriately maintain imaging characteristics. The number of correction unit is not limited to one, and it is desirable that a plurality of correction units be provided for the purpose of correcting changes in imaging characteristics caused by various disturbances during exposure and reducing adjustment error during projection lens manufacture.

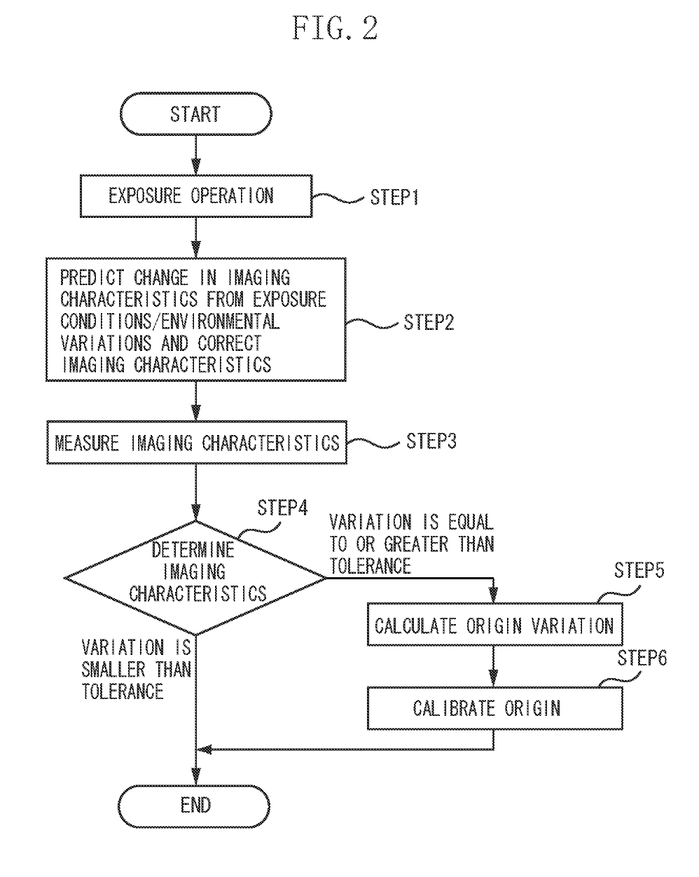

The first exemplary embodiment will be described below with reference to FIGS. 1 and 2.

In step 1, under predetermined environmental conditions, the projection exposure apparatus starts exposure operation while imaging characteristics of the projection optical system 3 are being optimally controlled by the correction unit 12.

At this time, a thermometer and a barometer (not shown) built in the apparatus senses disturbance factors that have changed during exposure, for example, a change in imaging characteristics due to environmental variation such as temperature and atmospheric pressure changes. Then, information about the disturbance factors is sent to a feedback control system 8. The feedback control system 8 includes an aberration change table T for temperature and atmospheric pressure changes. Based on the amount of temperature and atmospheric pressure changes ΔB, detected by the thermometer or barometer, the feedback control system 8 calculates an amount of aberration ΔA which varies with ΔB (ΔA=TΔB), by referencing the aberration change table T. Then, the feedback control system 8 calculates an amount of drive ΔC (ΔC=DbΔP) of the optical element 4 for correcting the varying aberration, where Db is the aberration sensitivity when driving the drive system. In step 2, the feedback control system 8 drives and controls the correction unit 12 based on the calculated values. Therefore, in step 2, the feedback control system 8 predicts changes in imaging characteristics due to environmental variation by using prestored information, and then controls the optical element 4 so as to reduce the changes in imaging characteristics.

In step 3, the imaging characteristics measurement unit 10 periodically measures imaging characteristics of the projection optical system 3, for example, for each starting lot.

In step 4, the imaging characteristics measurement unit 10 determines whether or not the change in imaging characteristics is within a preset tolerance.

In step 5, when the imaging characteristics measurement unit 10 perceives a change in imaging characteristics equal to or greater than the tolerance and determines that there is a deviation between the position of the optical element 4 corresponding to the output of the displacement sensor 6 and the actual position of the optical element 4, the imaging characteristics measurement unit 10 calculates an amount of deviation. The deviation between the position of the optical element 4 corresponding to the output of the displacement sensor 6 and the actual position of the optical element 4 is referred to as origin shift.

Then, in step 6, the imaging characteristics measurement unit 10 transfers information about the amount of origin shift to the correction unit 12 through the feedback control system 8, and the correction unit 12 calibrates the origin position stored in the storage unit.

In steps 1 to 6, the correction unit 12 minimizes the deviation between the position of the optical element 4 corresponding to the output of the displacement sensor 6 and the actual position of the optical element 4.

Calculation of the amount of origin shift and calibration of the origin will be described below.

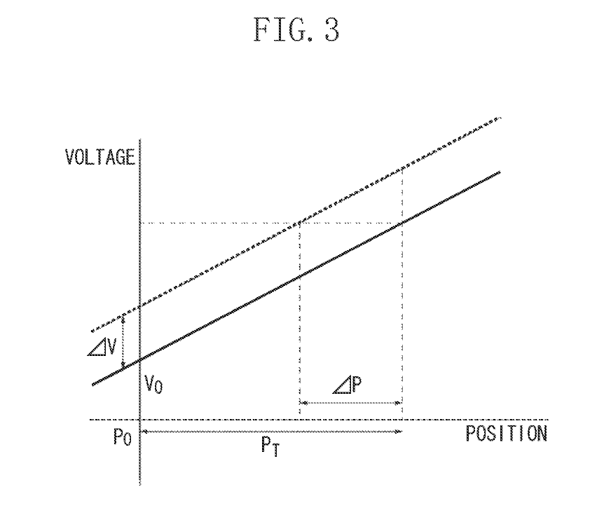

For example, when a position P of the optical element 4 is voltage-controlled in a system having the imaging characteristics shown in FIG. 3, the position P of the optical element 4 is controlled from an origin position P0 (measurement criterion) to P=P0+PT so as to correct the above-mentioned environmental variation factors, where PT is an amount of fluctuation in the position of the optical element 4 predicted from environmental variation. This allows the projection optical system 3 to constantly be free from the influence of environmental factors. However, in addition to environmental factors, the projection exposure apparatus itself may have fluctuation factors. For example, an aging-related change in posture of a mechanism, an aging-related expansion or contraction of a component, or an aging-related change in characteristics of an electrical element may cause an origin shift of a displacement sensor for measuring a displacement of the drive system. Therefore, it is necessary to periodically calibrate the origin of the displacement sensor. Specifically, a wave-front aberration measurement device (not shown) built in the projection exposure apparatus periodically measures a wave-front aberration at a plurality of points within a screen of the projection optical system 3, for example, once a month or for every 100 lots processed. The origin of the displacement sensor is managed, for example, such that the optical element 4 comes to a position at which a maximum value of wave-front aberration RMS values at a plurality of points within the screen is minimized (hereinafter referred to as wave-front aberration RMS minimum value).

The system is set up in advance for origin calibration. Specifically, in a periodical inspection, if the position of the drive unit at which the wave-front aberration RMS value is minimized deviates from the position in preceding inspection by a certain value or more, for example, if the position deviates by 5% or more of the entire stroke of the drive system, the correction unit 12 calibrates the origin of the sensor. When there is a plurality of drive units, a value used to determine that an origin shift has occurred is set for each drive unit.

When the imaging characteristics measurement unit 10 measures a change in imaging characteristics equal to or greater than a predetermined tolerance set depending on the measurement accuracy or control accuracy as a result of imaging characteristics measurement, the imaging characteristics measurement unit 10 calculates an amount of origin shift, ΔP, through operations. The correction unit 12 calibrates the origin position of the displacement sensor 6 by correcting a voltage value V0 at an origin position P0 (measurement criterion) with a control voltage value AV corresponding to the amount of origin shift, ΔP, that is, by updating V0 to V0+ΔV. The origin position of the displacement sensor stored in the storage unit is calibrated in this way to control the correction unit 12 with reference to the origin position. Thus, the wave-front aberration is optimally maintained. The step of calculating the amount of origin shift, ΔP, can make the calculation by referencing a database defining a relation between the position, posture and shape, and imaging performance of the optical element 4. For example, when there is only one correction unit, the amount of origin shift, ΔP, is calculated, as ΔP=ΔM/B where ΔM [ppm] is an amount of change in the imaging magnification and B [ppm/um] is a change rate of the magnification accompanying the origin shift. With a projection exposure apparatus including a plurality of optical elements, the amount of origin shift can be calculated by the formula (1), depending on the number of optical elements and the degree of freedom:

$$[ \begin{matrix}Δ {P}_{1} \\ Δ {P}_{2} \\ ⋮ \\ ⋮ \\ ⋮ \\ Δ {P}_{n}\end{matrix} ] = {[ \begin{matrix}{B}_{11} & {B}_{12} & … & … & … & {B}_{lm} \\ {B}_{21} & ⋱ & & & & \\ ⋮ & & ⋱ & & & \\ ⋮ & & & ⋱ & & \\ ⋮ & & & & {B}_{ij} & \\ {B}_{nl} & & & & & {B}_{n m}\end{matrix} ]}^{- 1} [ \begin{matrix}{k}_{1} \\ {k}_{2} \\ ⋮ \\ ⋮ \\ ⋮ \\ {k}_{m}\end{matrix} ] \qquad ( 1 )$$

where ΔPj (j=1 to m) is an amount of change in position, posture and shape of optical elements; ki (i=1 to n) is an amount of change in imaging characteristics; and Bij is a change rate for ΔPj relative to ki. For ki, the focal position, curvature of field, one-sided blur, imaging magnification, distortion, spherical aberration, astigmatism, coma, and other imaging characteristics can be selected.

If changes in imaging characteristics due to environmental variation such as atmospheric pressure, temperature, and humidity changes have been corrected and controlled, only changes due to origin shift of the displacement sensor 6 are measured as changes in imaging characteristics, thereby determining whether or not an origin shift has occurred. Of course, it is also possible to determine whether or not an origin shift has occurred, by separately measuring environmental variation factors and, based on measured changes in imaging characteristics, separating environmental variation factors in calculation by using the database defining a relation between environmental variation and changes in imaging characteristics.

It is desirable to execute steps 3 to 6 in a short time which does not affect the throughput of the projection exposure apparatus. As an imaging characteristics measurement unit configured to meet these demands and simply measure imaging characteristics in a short time with high precision, various methods such as an interference measurement method and a photoelectrical detector can be adopted.

With the interference measurement method, for example, light from the illumination optical system passes through a pinhole and a collimator lens to form a plane wave, and one piece of the light flux separated by a half mirror passes through the projection optical system to cause interference with a reference beam, thus an optical interference fringe can be obtained. Then, imaging characteristics can be measured by performing calculations for the optical interference fringe.

When a photoelectrical detector is used, an exposure light illuminates a dedicated pattern formed on a reticle surface and passes through the projection optical system. The photoelectrical detector arranged on the wafer stage receives the exposure light, and a signal from the detector is calculated, thus imaging characteristics can be obtained.

In a displacement measurement unit using a non-exposure light source, measurement can be performed regardless of measurement timing. However, even in a displacement measurement unit using an actual exposure light source, measurement can be performed without reducing the throughput by measuring imaging characteristics, for example, during wafer replacements or between jobs.

Many causes of change in measurement values of the displacement sensor are conceivable which are not related to variation of the optical elements. One possible cause is principled fluctuations in measurement values accompanying aging of the material of the displacement sensor. In a mechanism which forcibly deforms an optical element, for example, there possibly be a case where the displacement sensor does not directly monitor the optical element, i.e., it cannot capture its deformation, depending on a relation between the number and arrangements of displacement sensors.

Periodical calibration of the origin position of the displacement sensor can optimally maintain imaging characteristics by controlling the optical element with reference to the origin position.

In the above-mentioned exemplary embodiment, the correction unit 12 calibrates the origin by updating the origin position stored in the storage unit. However, it is also possible to separately store information about the amount of origin shift, without updating the origin position, and calibrate the origin by using the origin position and the stored amount of origin shift when operating the displacement sensor.

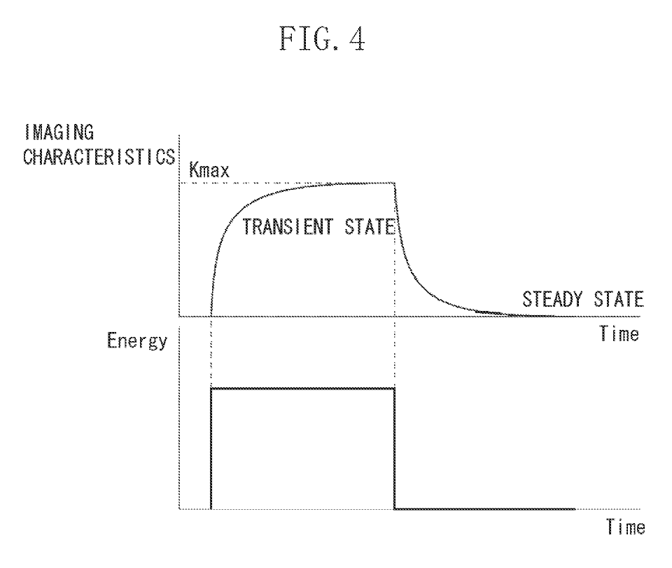

As shown in FIG. 4, according to the second exemplary embodiment of the present invention, it is known that imaging characteristics of the projection optical system change when a part of radiated exposure light is absorbed. This change k in imaging characteristics is represented by formula (2).

k=Φkmax−Φkmax/exp(t/K) (2)

where K is a time constant, t is the exposure time, Φ is a parameter determined by the lens system, and kmax is a saturation value of imaging characteristics. K and kmax vary depending on a cause of individual change in imaging characteristics. When there are more than one cause, an amount of change in imaging characteristics is represented by the summation of relevant changes.

By precalculating these parameters from the exposure energy and illumination conditions, the current state of the projection optical system can be predicted. When exposure is stopped, the change k returns to a state before exposure with the passing of time, by formula (3).

k=Φkmax/exp(t/K) (3)

Therefore, in a non-steady state in which imaging characteristics are not stable, it is desirable to predict changes from a stable state based on an operation history by using the formulas (2) and (3), and drive and control the correction unit to optimally maintain imaging characteristics. It is also desirable to predict changes from the stable state by using a learning function based on past results, and drive and control the correction unit to optimally maintain imaging characteristics. In this case, as a result of imaging characteristics measurement, a prediction error and a correction residue amount are measured in addition to steady-state imaging characteristics without an exposure load. When the imaging characteristics measurement unit 10 measures a change in imaging characteristics exceeding the preset tolerance, it is possible to separate and determine the change as an origin shift of the displacement sensor, and calibrate the origin.

When a change in imaging characteristics by an exposure load is equal to or greater than the predetermined tolerance as mentioned above, the change in imaging characteristics due to the exposure load is first obtained through calculation. An amount of change in imaging characteristics due to the exposure load is subtracted from a deviation from the reference value of the measured imaging characteristics. Then, the origin can be calibrated recognizing that the obtained value is caused by an origin shift.

This enables high-precision calibration without error due to the operating state of the apparatus.

Although FIG. 2 illustrates an exemplary embodiment during operation of the exposure process apparatus, imaging characteristics can naturally be measured while the apparatus is not operating (not during exposure operation). When the change in imaging characteristics due to the exposure load is smaller than the predetermined tolerance at the time of origin calibration, the correction unit 12 calibrates the origin on the premise that deviation of the result of imaging characteristics measurement from the reference value is caused solely by variation in the origin position. This process makes it easier to calibrate the origin.

In a steady state without an exposure load in which the imaging performance is stable, for example, while the apparatus is not in exposure operation, separation of environmental variation factors in this way makes it easier to determine change in the imaging performance due to origin shift of the displacement sensor, and calibrate the origin.

This enables high-precision calibration with little error due to the operating state of the apparatus.

Possible causes of origin shift of the displacement sensor include long-term drift accompanying aging of a component used for the sensor itself and short-term variation accompanying power ON/OFF operation of the apparatus and recovery from the reset sequence.

For long-term variation, it is desirable to periodically determine whether or not an origin shift has occurred, for example, once a day or once for every 100 lots, and calibrate the origin.

Also for short-term variation, it is desirable to determine whether or not an origin shift has occurred in a similar way immediately after turning ON the power of the apparatus and immediately after reset operation, and calibrate the origin.

This process makes it possible to avoid calibration during operation of the apparatus, thus an apparatus having a high throughput can be provided.

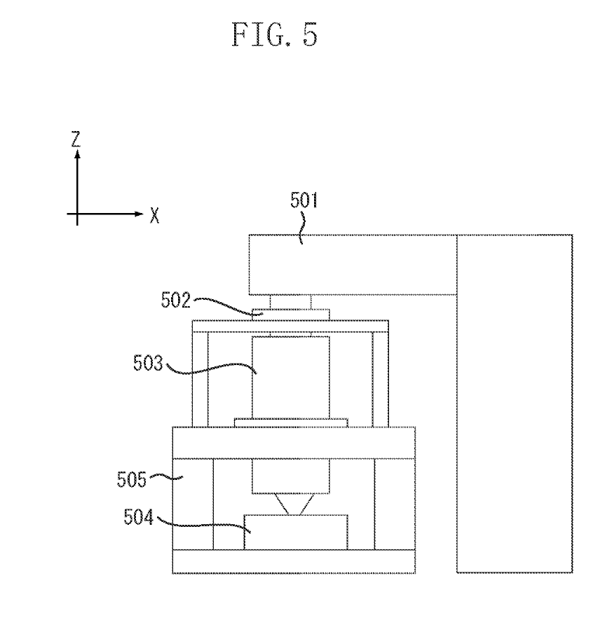

An overview of the entire exposure apparatus will be described below. An exposure apparatus 505 includes an illumination apparatus 501, a reticle stage 502 on which a reticle (original plate) is mounted, a projection optical system 503, and a wafer stage 504 on which a wafer (substrate) is mounted, as shown in FIG. 5. The exposure apparatus 505 projects a circuit pattern formed on the reticle onto the wafer to be exposed. The exposure apparatus 505 may employ the step and repeat projection exposure method or the step and scan projection exposure method.

The illumination apparatus 501 includes a light source unit and an illumination optical system, and illuminates the reticle on which a circuit pattern is formed. The light source unit uses, for example, laser as alight source. Usable laser includes ArF excimer laser with a wavelength of about 193 nm, KrF excimer laser with a wavelength of about 248 nm, and F2 excimer laser with a wavelength of about 157 nm. However, the type of laser is not limited to excimer laser, and, for example, YAG laser may be used. The number of laser systems is not limited, either. When using laser as a light source, it is desirable to use a light flux shaping optical system for shaping a parallel laser light flux from a laser light source into a desired laser beam shape and an incoherentizing optical system for converting a coherent laser light flux into an incoherent one. The light source that can be used for the light source unit is not limited to laser, but one or a plurality of mercury lamps and xenon lamps can be used.

The illumination optical system includes a lens, a mirror, a light integrator, and a diaphragm, and illuminates a mask.

The projection optical system 503 can be an optical system which includes a plurality of lens elements, or an optical system (catadioptric optical system) which includes a plurality of lens elements and at least one concave mirror. The projection optical system 503 can be an optical system which includes a plurality of lens elements and at least one diffractive optical element such as a kinoform, or an optical system of all-mirror type.

The reticle stage 502 and the wafer stage 504 can be moved, for example, by a linear motor. In the case of the step and scan projection exposure method, the two stages move in synchronization with each other. To adjust the position of the reticle pattern onto the wafer, one or both of the wafer and reticle stages is separately provided with an actuator.

Such an exposure apparatus is used for manufacture of semiconductor devices such as semiconductor integrated circuits and devices with fine patterns formed thereon such as micromachines and thin film magnetic heads.

Devices (semiconductor integrated circuit elements, liquid crystal display elements, etc.) are manufactured through a process of exposing a substrate (wafer, glass substrate, etc.) coated with a photosensitive material by using the exposure apparatus according to any one of the above-mentioned exemplary embodiments; a process of developing the substrate; and other known processes.

### OTHER EMBODIMENTS

Aspects of the present invention can also be realized by a computer of a system or apparatus (or devices such as a CPU or MPU) that reads out and executes a program recorded on a memory device to perform the functions of the above-described embodiments, and by a method, the steps of which are performed by a computer of a system or apparatus by, for example, reading out and executing a program recorded on a memory device to perform the functions of the above-described embodiments. For this purpose, the program is provided to the computer for example via a network or from a recording medium of various types serving as the memory device (e.g., computer-readable medium). In such a case, the system or apparatus, and the recording medium where the program is stored, are included as being within the scope of the present invention.

While the present invention has been described with reference to exemplary embodiments, it is to be understood that the invention is not limited to the disclosed exemplary embodiments. The scope of the following claims is to be accorded the broadest interpretation so as to encompass all modifications, equivalent structures, and functions.

This application claims priority from Japanese Patent Application No. 2008-296692 filed Nov. 20, 2008, which is hereby incorporated by reference herein in its entirety.

What is claimed is:

1. A projection exposure apparatus which includes an optical element, and projects a pattern formed on a first object onto a second object to be exposed through a projection optical system for correcting imaging characteristics by controlling the optical element, the projection exposure apparatus comprising:
a displacement measurement unit configured to measure a displacement of the optical element;
a storage unit configured to store a measurement criterion of the displacement measurement unit;
an imaging characteristics measurement unit configured to measure imaging characteristics of the projection optical system; and
a calibration unit configured to calibrate the measurement criterion based on a result of measurement by the imaging characteristics measurement unit.

2. The projection exposure apparatus according to claim 1, further comprising:
a calculation unit configured to calculate an amount of deviation between the position of the optical element corresponding to an output of the displacement measurement unit and the actual position of the optical element,
wherein the calibration unit calibrates the measurement criterion based on the amount of deviation calculated by the calculation unit.

3. The projection exposure apparatus according to claim 1, further comprising:
a unit configured to predict imaging characteristics of the projection optical system and correct the position of the optical element based on information about a change in imaging characteristics of the projection optical system due to environmental variation.

4. The projection exposure apparatus according to claim 1, wherein the imaging characteristics include at least one of the focal position, curvature of field, one-sided blur, imaging magnification, distortion, spherical aberration, astigmatism, and coma.

5. A method for calibrating a measurement criterion of a displacement measurement unit used when measuring a displacement of an optical element included in a projection optical system, the method comprising:
measuring imaging characteristics of the projection optical system; and
calibrating the measurement criterion based on a result of the imaging characteristics measurement.

6. The method for calibrating a measurement criterion according to claim 5, the method further comprising:
calculating an amount of deviation between the position of the optical element corresponding to an output of the displacement measurement unit and the actual position of the optical element based on a result of the imaging characteristics measurement,
wherein the measurement criterion is calibrated on the basis of the amount of deviation.

7. The method for calibrating a measurement criterion according to claim 6, the method further comprising:
determining whether or not the change in imaging characteristics is within a range of a tolerance based on a result of the imaging characteristics measurement,
wherein, when the change in imaging characteristics is determined to be equal to or greater than the tolerance, an amount of deviation between the position of the optical element corresponding to an output of the displacement measurement unit and the actual position of the optical element are calculated to calibrate the measurement criterion.

8. The method for calibrating a measurement criterion according to claim 5, wherein the imaging characteristics measurement is performed except during exposure operation.

9. The method for calibrating a measurement criterion according to claim 5, wherein, when the measurement operation performs the imaging characteristics measurement during exposure operation, the measurement criterion is calibrated on the basis of a result obtained by predicting a change in imaging characteristics by exposure operation.

10. A method for manufacturing a device, comprising:
projecting a pattern formed on an original plate onto a substrate to be exposed by using a projection exposure apparatus; and
developing the exposed substrate,
wherein the projection exposure apparatus comprises:
a unit which includes an optical element and is configured to correct imaging characteristics by controlling the optical element;
a displacement measurement unit configured to measure a displacement of the optical element;
a storage unit configured to store a measurement criterion of the displacement measurement unit;
an imaging characteristics measurement unit configured to measure imaging characteristics of the projection optical system; and
a calibration unit configured to calibrate the measurement criterion based on a result of measurement by the imaging characteristics measurement unit.
